(19) United States
(12) Patent Application Publication
(10) Pub. No.: US 2005/0130434 A1
(43) Pub. Date: Jun. 16, 2005

(54) Method of surface pretreatment before selective epitaxial growth

(75) Inventors: Chin-Cheng Chien, Hsin-Chu City (TW); Ya-Lun Cheng, Taipei City (TW); Yu-Ren Wang, Tainan City (TW); Neng-Hui Yang, Hsin-Chu City (TW)

Correspondence Address: ARENT FOX KINTNER PLOTKIN & KAHN, PLLC, Suite 400, 1050 Connecticut Avenue, N.W., Washington, DC, 20036-5339, US

(73) Assignee: UNITED MICROELECTRONICS CORP.

(21) Appl. No.: 10/734,197

(22) Filed: Dec. 15, 2003

(51) Int. Cl. C30B 1/00; H01L 21/20

(52) U.S. Cl. 438/706; 438/503; 438/504

(57) ABSTRACT

A method of surface pretreatment before selective epitaxial growth is provided. A semiconductor substrate having metal-oxide-semiconductor devices formed thereon is provided, and a lightly dry etching process with a carbon-free plasma source is performed to remove a portion of the semiconductor substrate. Then, a selective epitaxial growth process is performed to form a semiconductor layer on the semiconductor substrate. A clean surface for selective epitaxial growth is provided by the lightly dry etching process, which can resolve the undercut issue and surface roughness.

### BACKGROUND OF THE INVENTION

1. Field of the Invention

The present invention relates to a method of surface pretreatment in a semiconductor process, and more particularly to a method of surface pretreatment before selective epitaxial growth process.

2. Description of the Prior Art

As semiconductor devices are scaled to smaller dimensions, generally in the sub-0.1 μm region, it is highly desirable and generally necessary to fabricate such devices with source/drain shallow junction. However, when a silicide is formed on the source/drain region, the silicide easily contacts with the shallow junction to make junction leakage. Therefore, an approach to resolve the leakage problem is to use raised source/drain. Since the raised source/drain is formed upward above the substrate, the silicide could not easily contact with the shallow junction, and then the junction leakage can be reduced.

FIG. 1A to 1B shows various steps for forming a conventional N-channel metal-oxide-semiconductor device with raised source/drain. The conventional method includes the following steps. Firstly, referring to FIG. 1A, a P type silicon substrate 100 is provided. A plurality of shallow trench isolations 101 is formed in the substrate 100. Then, a gate oxide 102 and a gate electrode 103 are sequentially formed between each pair of the shallow trench isolations 101 on the substrate 100. Subsequently, placing an implant mask on the substrate 100 and by way of ion implantation, to form an N type lightly doped drain region between the gate electrode 103 and each of the pair of the shallow trench isolations 101 in the substrate 100. Thereafter, forming a conformal silicon dioxide layer 105 on the gate electrode 103 and then forming a silicon nitride layer 106 on the conformal silicon dioxide layer 105. The conformal silicon dioxide layer 105 and the silicon nitride layer 106 are anisotropically etched by way of reactive ion etch method to form a pair of first sidewall spacers 105 around the gate electrode 103 and a pair of second sidewall spacers 106 around the first sidewall spacers 105.

Referring to FIG. 1B, next, a raised source/drain 107 is to be formed upward on each of the pair of the lightly doped drain region 104. The raised source/drain 107 is generally formed by a selective epitaxial growth process. However, a clean surface for selective epitaxial growth is very important. The portions of the substrate 100 having native oxide, oxygen and carbon species remained thereon would not grow the epitaxial layer, and making holes formed in the epitaxial layer growing on the substrate 100, which degrade the epitaxial layer. Therefore, surface pretreatment is a key for the selective epitaxial growth process. Conventionally, the surface pretreatment is performed by a wet etching method with strong acid, such as aqueous hydrofluoric acid (HF) solution, to remove the native oxide and other contaminants on the substrate 100. However, as shown in FIG. 1B, the surface pretreatment with strong acid leads to serious undercut of the first sidewall spacer 105. The undercut of the first sidewall spacer 105 make portions of the gate electrode 103 exposed. When a silicide layer (not shown) is formed on the gate electrode 103 and raised source/drain 107, the silicide layer would bridge the gate electrode 103 and raised source/drain 107. A current leakage is thus happened between the gate electrode 103 and raised source/drain 107. However, when surface pretreatment is performed with weak acid, which would not effectively remove oxygen and carbon species remained on the substrate 100, and leads to a rough surface of the epitaxial layer.

Accordingly, it is an intention to provide a method of surface pretreatment before selective epitaxial growth, which can overcome the drawbacks of the conventional methods.

### SUMMARY OF THE INVENTION

It is one objective of the present invention to provide a method of surface pretreatment before selective epitaxial growth process, which utilizes a lightly dry etching process to remove a portion of a semiconductor substrate so as to remove native oxide on the semiconductor substrate. Hence, a clean surface suitable for the selective epitaxial growth is obtained.

It is another objective of the present invention to provide a method of surface pretreatment before selective epitaxial growth process, which utilizes a lightly dry etching process instead of a conventional wet etching method to remove native oxide on a semiconductor substrate. The undercut issue and surface roughness encountered in the conventional wet etching method are thus resolved.

It is a further objective of the present invention to provide a method of surface pretreatment before selective epitaxial growth process, which is easily attained and does not increase additional steps for manufacturing semiconductor devices using selective epitaxial growth.

In order to achieve the above objectives of this invention, the present invention provides a method of surface pretreatment before selective epitaxial growth process. A semiconductor substrate having metal-oxide-semiconductor devices formed thereon is provided. And, a dry etching process with a carbon-free plasma source is performed to remove a portion of the semiconductor substrate. Then, a selective epitaxial growth process is performed to form a semiconductor layer on the semiconductor substrate.

The present dry etching process can effectively remove native oxide on the semiconductor substrate, and hence providing a clean surface for the selective epitaxial growth. A semiconductor layer with good quality is thus obtained.

### BRIEF DESCRIPTION OF THE DRAWINGS

The objectives and features of the present invention as well as advantages thereof will become apparent from the following detailed description, considered in conjunction with the accompanying drawings.

FIG. 1 to 1B shows cross sectional views of various steps of the conventional method for forming a semiconductor device with raised source/drain regions; and

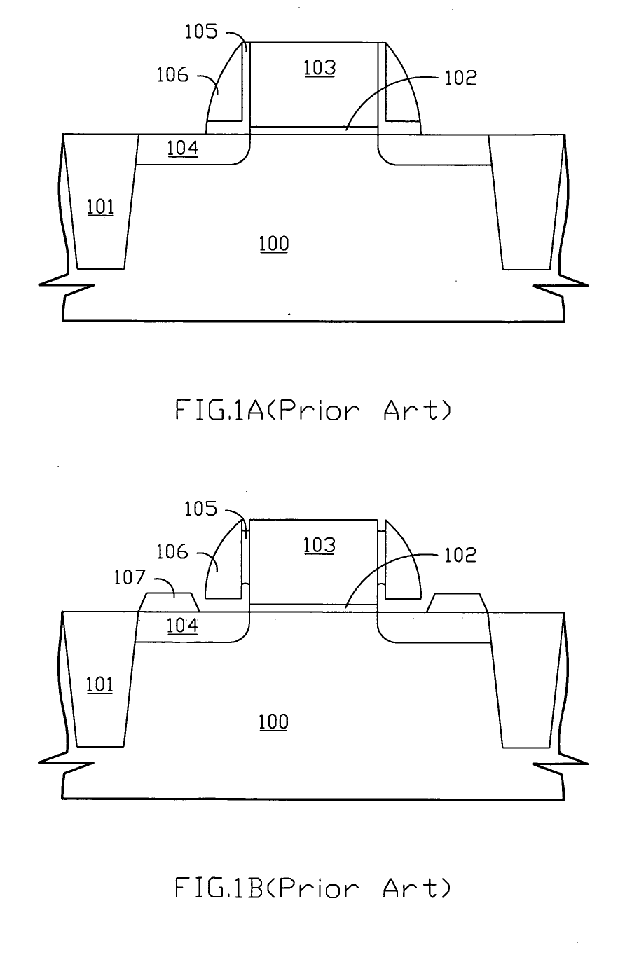

FIG. 2A to 2B shows cross sectional views of various steps of the present method of forming a semiconductor device using selective epitaxial growth.

### DESCRIPTION OF THE EMBODIMENTS

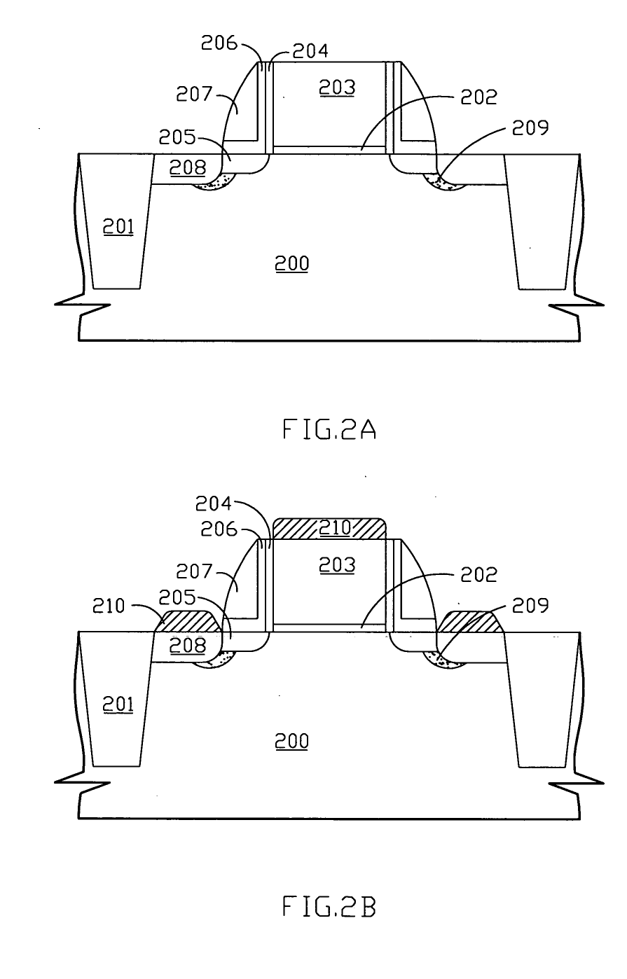

The present invention will be described in detail with reference to the accompanying drawings. The present invention provides a method of surface pretreatment before selective epitaxial growth process, which can resolve the undercut issue and surface roughness of the epitaxial layer. Referring to FIG.2A, a semiconductor substrate 200, such as a silicon substrate, with a first conductive type, is firstly provided. The first conductive type is either of N type and P type. A plurality of shallow trench isolations 201 is formed in the semiconductor substrate 200. Other isolation region, for example, field oxide, can be substituted for the shallow trench isolation 201. Then, a gate oxide 202 and a polysilicon gate electrode 203 are sequentially formed between each pair of the shallow trench isolations 201 on the semiconductor substrate 200. Next, forming an offset spacer of silicon dioxide 204 around the gate oxide 202 and the polysilicon gate electrode 203. Then, forming a lightly doped drain region 205 with a second conductive type opposite to the first conductive type in the semiconductor substrate 200 between the polysilicon gate electrode 203 and each of the shallow trench isolations 201. When the semiconductor substrate 200 has a P type conductivity, an N type lightly doped drain region 205 can be formed under the following conditions: arsenic ion is implanted with an implantation energy of 5 to 15 Kev at an implantation dose of 5×10¹³ to 5×10¹⁵ ions/cm². When the semiconductor substrate 200 has an N type conductivity, a P type lightly doped drain region 205 can be formed under the following conditions: boron ion is implanted with an implantation energy of 5 to 15 Kev at an implantation dose of 5×10¹³ to 5×10¹⁵ ions/cm². A silicon dioxide liner layer 206 is formed around the offset spacer 204. Then, a spacer of silicon nitride 207 is formed around the silicon dioxide liner layer 206. Subsequently, a source/drain region 208 with the second conductive type is formed beside the lightly doped drain region 205. Following, tilting the whole semiconductor substrate 200 with a predetermined angle and implanting a pocket region 208 with the first conductive type on the interface of the lightly doped drain region 205 and the semiconductor substrate 200. When the semiconductor substrate 200 has a P type conductivity. The pocket implantation can be carried out under the following conditions: boron ion is implanted with an implantation energy of 15 to 25 Kev at an implantation dose of 1×10¹³ to 5×10¹⁴ ions/cm². BF₂⁺ ion can be substituted for boron ion, with an implantation energy of about 30 Kev to 40 Kev at an implantation dose of 1×10¹³ to 5×10¹⁴ ions/cm². When the semiconductor substrate 200 has an N type conductivity. The pocket implantation can be carried out under the following conditions: arsenic ion is implanted with an implantation energy of 130 to 150 Kev at an implantation dose of 1×10¹³ to 5×10¹⁴ ions/cm². The pocket region 208 is used to prevent the punch through between the source/drain regions 207. Thereafter, a thermal annealing process is performed to active the dopants of the lightly doped drain regions 205, source/drain regions 207 and the pocket regions 208. The thermal annealing process can be a spike rapid thermal annealing process, arc annealing process and a laser annealing process. Under the thermal annealing process, the offset spacer 204 can control the distance of dopants diffusion of the lightly doped drain region 205 toward the channel region.

Referring to FIG. 2B, following, a selective epitaxial growth process is to be performed to form a semiconductor layer (not shown) on the exposed portions of the semiconductor substrate 200. The semiconductor layer can be silicon, germanium, or a compound of silicon and germanium. A surface pretreatment process is performed prior to the selective epitaxial growth process. The surface pretreatment process is used to provide a clean surface for the selective epitaxial growth. In the present invention, a lightly dry etching process with a carbon-free plasma source containing hexaflorosulfur (SF₆) diluted with ambient gas is performed to remove the exposed portion of the semiconductor substrate 200 around 20-50 angstroms. The ambient gas can be a kind of inert gas, such as helium, neon, argon and nitrogen, or hydrogen gas. The lightly dry etching process can be performed under the following conditions: hexaflorosulfur (SF₆) to the ambient gas has a volume ratio between about 0.5% and 5% , operating pressure is about 10 mtorr, operating power is between about 20 watts to about 500 watts, and an etching time is within about 1 minutes. Since the lightly dry etching process partially removes the exposed portion of the semiconductor substrate 200, the native oxide and other contaminants remained on the surface of the semiconductor substrate 200 can be removed away at the same time. Hence, a clean surface can be provided. Then, a selective epitaxial growth process is performed to grow a semiconductor layer on the source/drain region 208 and the polysilicon gate electrode 203. The selective epitaxial growth process can be performed in an epitaxial chamber by a low pressure chemical vapor deposition (LPCVD) method or a ultra-high vacuum chemical deposition method (UHVCVD) with a reaction mixture of dichlorosilane (DCS), HCl and H₂ at a temperature less than 800° C. However, when the whole semiconductor substrate 200 is not directly placed in the epitaxial chamber after the surface pretreatment, a lightly wet etch with aqueous hydrofluoric acid solution can be performed to remove the native oxide probably formed on the semiconductor substrate 200. And, a baking process with hydrogen ambient gas at a temperature less than 750° C. can be followed to remove oxygen species probably remained on the semiconductor substrate 200. Subsequently, a silicide layer 210 is formed on the source/drain regions 208 and the polysilicon gate electrode 203 by performing a salicide process. Namely, a metal layer is deposited on the semiconductor layer, and then a portion of the metal layer is changed into silicide by means of a thermal process. The other portion of the metal layer, which is not changed into the silicide layer, is removed. The metal layer can be Ti, Co, Ta, Ni, Pt, or a compound of the above metals.

The present invention utilizes a lightly dry etching process instead of the wet etching method with strong acid in the surface pretreatment process. Since the lightly dry etching process anisotropically etches a portion of the semiconductor substrate 200, the undercut of the offset spacer 204 and the silicon dioxide liner layer 206 is avoided. A clean surface for the selective epitaxial growth also can be provided. And, the present method does not increase additional steps for manufacturing semiconductor devices using selective epitaxial growth.

The embodiments are only used to illustrate the present invention, not intended to limit the scope thereof. Many modifications of the embodiments can be made without departing from the spirit of the present invention.

1. A method of surface pretreatment before selective epitaxial growth process, comprising:
providing a semiconductor substrate having metal-oxide-semiconductor devices each comprising a gate electrode, a source region and a drain region;
performing a dry etching process with a carbon-free plasma source to remove a portion of said semiconductor substrate; and
performing a selective epitaxial growth process to form a semiconductor layer on said gate electrode, said source and drain regions for a salicide process.

2. The method of claim 1, wherein said dry etching process is performed with a carbon-free plasma source containing hexaflorosulfur (SF₆) diluted with ambient gas.

3. The method of claim 2, wherein said dry etching process is performed with a carbon-free plasma source containing hexaflorosulfur (SF₆) diluted with ambient gas selected from a group consisting of helium, neon, argon, hydrogen and nitrogen.

4. The method of claim 2, wherein said dry etching process is performed with a carbon-free plasma source containing hexaflorosulfur (SF₆) having a volume ratio between about 0.5% and 5%.

5. The method of claim 3, wherein said dry etching process is performed with a carbon-free plasma source containing hexaflorosulfur (SF₆) having a volume ratio between about 0.5% and 5%.

6. The method of claim 4, wherein said dry etching process is performed at a pressure about 10 mtorr and a power between about 20 watts to about 500 watts, and an etching time within about 1 minutes.

7. The method of claim 5, wherein said dry etching process is performed at a pressure about 10 mtorr and a power between about 20 watts to about 500 watts, and an etching time within about 1 minutes.

8. The method of claim 1, wherein said dry etching process is performed to remove said semiconductor substrate about 20-50 angstroms.

9. The method of claim 2, wherein said dry etching process is performed to remove said semiconductor substrate about 20-50 angstroms.

10. The method of claim 1, wherein further comprising a baking process performed with hydrogen ambient gas at a temperature less than 750° C. prior to said selective epitaxial growth process.

11. A method of forming a semiconductor device using selective epitaxial growth, comprising:
providing a semiconductor substrate with a first conductivity;
forming a plurality of isolation regions on said semiconductor substrate;
sequentially forming a gate dielectric layer and a gate electrode on said semiconductor substrate between each pair of said isolation regions;
forming a lightly doped drain region with a second conductivity opposite to said first conductivity ins aid semiconductor substrate between said gate electrode and each said isolation region;
forming a first spacer around said gate dielectric layer and said gate electrode;
forming a source/drain region with said second conductivity beside said lightly doped drain region in said semiconductor substrate;
performing a dry etching process with a carbon-free plasma source to remove a portion of said semiconductor substrate;
performing a selective epitaxial growth process to form a semiconductor layer on said gate electrode, said source and drain regions;
forming a metal layer on said semiconductor layer; and
performing a salicide process to form a silicide layer on said gate electrode, said source and drain regions.

12. The method of claim 11, wherein said dry etching process is performed with a carbon-free plasma source containing hexaflorosulfur (SF₆) diluted with ambient gas.

13. The method of claim 12, wherein said dry etching process is performed with a carbon-free plasma source containing hexaflorosulfur (SF₆) diluted with ambient gas diluted with ambient gas selected from a group consisting of helium, neon, argon, hydrogen and nitrogen.

14. The method of claim 12, wherein said dry etching process is performed with a carbon-free plasma source containing hexaflorosulfur (SF₆) having a volume ratio between about 0.5% and 5%.

15. The method of claim 13, wherein said dry etching process is performed with a carbon-free plasma source containing hexaflorosulfur (SF₆) having a volume ratio between about 0.5% and 5%.

16. The method of claim 14, wherein said dry etching process is performed at a pressure about 10 mtorr and a power between 20 watts to about 500 watts, and an etching time within about 1 minutes.

17. The method of claim 15, wherein said dry etching process is performed at a pressure about 10 mtorr and a power between 20 watts to about 500 watts, and an etching time within about 1 minutes.

18. The method of claim 11, wherein further comprising a baking process performed with hydrogen ambient gas at a temperature less than 750° C. prior to said selective epitaxial growth process.

19. The method of claim 11, wherein further comprising a step of forming a second spacer around said gate dielectric layer and said gate electrode prior to forming said first spacer.

20. The method of claim 11, wherein said metal layer is selected from a group consisting of Ti, Co, Ta, Ni, Pt and a compound thereof.
